(19) United States
(12) Patent Application Publication
(10) Pub. No.: US 2026/0076204 A1
(43) Pub. Date: Mar. 12, 2026

(54) SEMICONDUCTOR PACKAGE

(71) Applicant: SAMSUNG ELECTRONICS CO., LTD., Suwon-si (KR)

(72) Inventors: Jaewon Kim, Suwon-si (KR); Jinsu Kim, Suwon-si (KR); Seunghyeon Park, Suwon-si (KR)

(73) Assignee: SAMSUNG ELECTRONICS CO., LTD., Suwon-si (KR)

(21) Appl. No.: 19/272,400

(22) Filed: Jul. 17, 2025

(30) Foreign Application Priority Data
Sep. 12, 2024 (KR) 10-2024-0124897

(51) Int. Cl. H01L 23/00

(52) U.S. Cl. CPC H10W 42/121

(57) ABSTRACT

A semiconductor package may include a package substrate including mounting region and an edge region surrounding the mounting region, one or more semiconductor devices on the mounting region of the package substrate, a stiffener on the edge region of the package substrate, the stiffener having a first surface facing the package substrate and a second surface opposite to the first surface, and an adhesive member between the package substrate and the stiffener to attach the stiffener to the package substrate. The stiffener includes a reinforcement rod that reinforces the package substrate and adhesive receiving grooves in a lower edge portion of the reinforcement member that are exposed from side portions of the reinforcement member, and each of the adhesive receiving grooves has a depth from the first surface of the stiffener to accommodates a portion of the adhesive member.

### PRIORITY STATEMENT

This application claims priority under 35 U.S.C. § 119 to Korean Patent Application No. 10-2024-0124897, filed on Sep. 12, 2024, in the Korean Intellectual Property Office (KIPO), the contents of which being herein incorporated by reference in their entirety.

### BACKGROUND

Example embodiments relate to a semiconductor package and, more particularly, to a semiconductor package including a stiffener configured to prevent warpage.

In a semiconductor package, a thermal interface material (TIM) may be used as an adhesive member to attach a stiffener to the package substrate. It is advantageous to control the flow of the thermal interface material so that the thermal interface material sufficiently covers bonding surfaces of the stiffener and the package substrate while preventing the thermal interface material from overflowing from the package substrate.

### SUMMARY

It is an aspect to provide a semiconductor package including a stiffener having a plurality of recesses that are able to control flow of adhesive member.

According to an aspect of one or more example embodiments, there is provided a semiconductor package includes a package substrate including a mounting region and an edge region surrounding the mounting region; at least one semiconductor device on the mounting region of the package substrate; a stiffener on the edge region of the package substrate, the stiffener having a first surface facing the package substrate and a second surface opposite to the first surface; and an adhesive member between the package substrate and the stiffener to attach the stiffener to the package substrate. The stiffener includes a reinforcement rod that reinforces the package substrate and a plurality of adhesive receiving grooves in a lower edge portion of the reinforcement rod that are exposed from side portions of the reinforcement rod, and each of the plurality of adhesive receiving grooves has a depth from the first surface of the stiffener to accommodate a portion of the adhesive member . . .

According to another aspect of one or more example embodiments, there is provided a semiconductor package includes a package substrate including a mounting region and an edge region surrounding the mounting region; an interposer disposed on the mounting region of the package substrate; at least one semiconductor device mounted on the interposer; a stiffener on the edge region of the package substrate, the stiffener including a reinforcement rod that reinforces the package substrate and a plurality of adhesive receiving grooves provided in a lower edge of the reinforcement rod and exposed from both side portions of the reinforcement rod; and an adhesive member between the package substrate and the stiffener to attach the stiffener to the package substrate, wherein the adhesive member covers a lower surface of the reinforcement rod and is at least partially accommodated in the plurality of adhesive receiving grooves.

According to yet another aspect of one or more example embodiments, there is provided a semiconductor package comprising a package substrate including a mounting region and an edge region surrounding the mounting region, the package substrate having first substrate recesses and second substrate recesses on the edge region and disposed along the mounting region; at least one semiconductor device on the mounting region of the package substrate; a stiffener on the edge region of the package substrate along an outer surface portion of the package substrate, the stiffener including a plurality of adhesive receiving grooves, the plurality of adhesive receiving grooves including a plurality of inner recesses and a plurality of outer recesses, the plurality of inner recesses extending from an inner surface of the stiffener into the stiffener and corresponding to the first substrate recesses, the plurality of outer recesses extending from an outer surface of the stiffener into the stiffener and corresponding to the second substrate recesses; and an adhesive member between the package substrate and the stiffener to cover one surface of the stiffener, the adhesive member being at least partially accommodated in the plurality of adhesive receiving grooves.

### BRIEF DESCRIPTION OF THE DRAWINGS

FIG. 1 is a cross-sectional view illustrating a semiconductor package in accordance with example embodiments.

FIG. 2 is a plan view illustrating the semiconductor package of FIG. 1.

FIG. 3 is an enlarged cross-sectional view illustrating portion ‘M1’in FIG. 2.

FIG. 4 is a perspective view illustrating a stiffener in accordance with example embodiments.

FIG. 5 is an enlarged view illustrating portion ‘M2’ in FIG. 4.

FIG. 6 is a plan view illustrating the stiffener in FIG. 1.

FIG. 7A is an enlarged view illustrating portion ‘M3’ in FIG. 6.

FIGS. 7B to 7E are enlarged views illustrating various shapes of adhesive receiving grooves in accordance to example embodiments.

FIGS. 8 to 20 are views illustrating a method of manufacturing a semiconductor package in accordance with example embodiments.

FIG. 21 is a cross-sectional view illustrating a semiconductor package in accordance with example embodiments.

FIG. 22 is an enlarged cross-sectional view illustrating portion ‘M5’ in FIG. 21.

FIGS. 23 to 29 are views illustrating a method of manufacturing a semiconductor package in accordance with example embodiments.

FIG. 30 is a cross-sectional view illustrating a semiconductor package in accordance with example embodiments.

### DETAILED DESCRIPTION

In order to prevent warpage of a semiconductor package, a stiffener may be attached to a package substrate. As described above, a thermal interface material (TIM) may be used as an adhesive member to attach the stiffener to the package substrate. However, if an amount of the thermal interface material is insufficient, there are disadvantages such as insufficient adhesive strength, reduced warpage prevention effect and reduced thermal conductivity. On the other hand, if the amount of the thermal interface material is excessive, there are disadvantages that a phenomenon in which the thermal interface material overflows from the package substrate to the outside (bleeding phenomenon) may occur, which may cause process defects such as jamming in process equipment and appearance defects in subsequent processes, especially in a solder ball attachment process. Therefore, it may be advantageous to control the flow of the thermal interface material so that the thermal interface material sufficiently covers the bonding surfaces of the stiffener and the package substrate while preventing the thermal interface material from overflowing from the package substrate.

According to various example embodiments, a semiconductor package may include a package substrate having a mounting region and an edge region surrounding the mounting region, at least one semiconductor device mounted on the mounting region of the package substrate, a stiffener disposed on the edge region of the package substrate, and an adhesive member disposed between the package substrate and the stiffener to attach the stiffener to the package substrate. The stiffener may include a reinforcement rod configured to prevent warpage of the package substrate and a plurality of adhesive receiving grooves provided in a lower edge of the reinforcement rod to be exposed from both side portions of the reinforcement rod. Accordingly, the plurality of adhesive receiving grooves may prevent the adhesive member from overflowing from the package substrate to the outside. Since the plurality of adhesive receiving grooves are provided in the edge of the reinforcement rod, the plurality of adhesive receiving grooves may help the adhesive member sufficiently cover a space between the stiffener and the package substrate. Thus, the stiffener may prevent warpage of the package substrate.

Hereinafter, various example embodiments will be explained in detail with reference to the accompanying drawings.

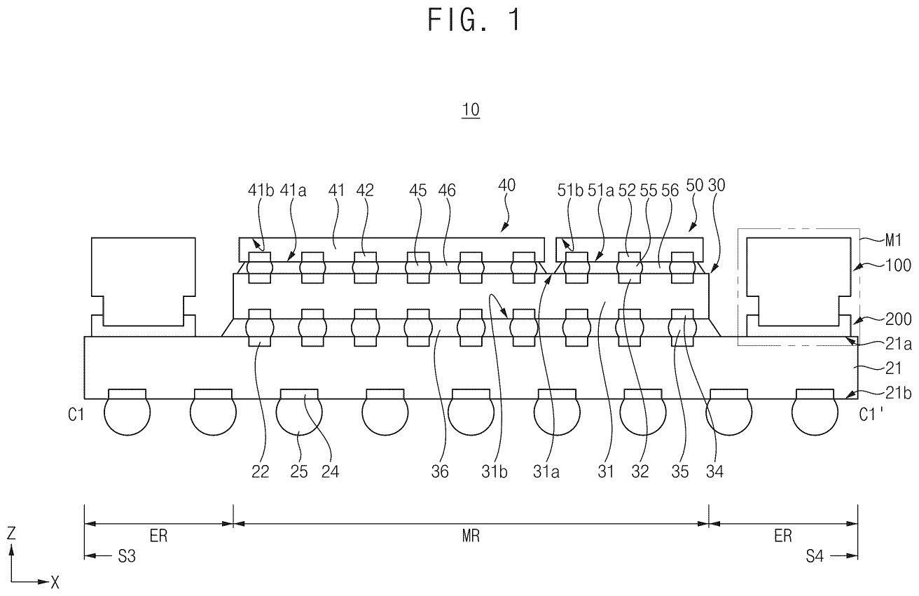

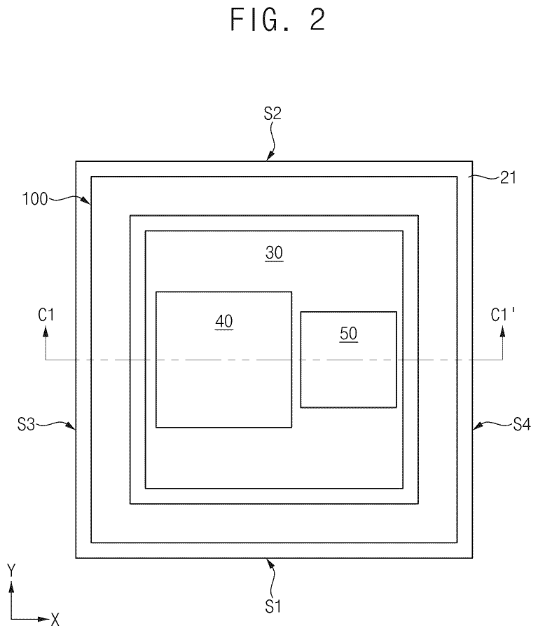

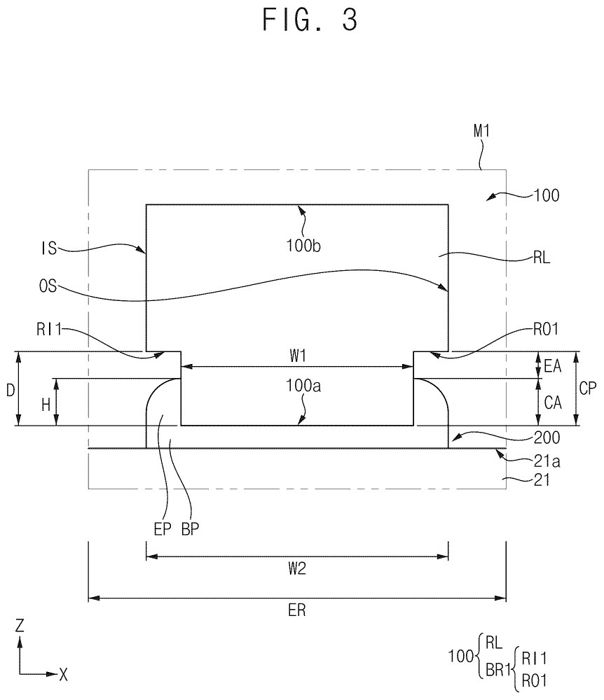

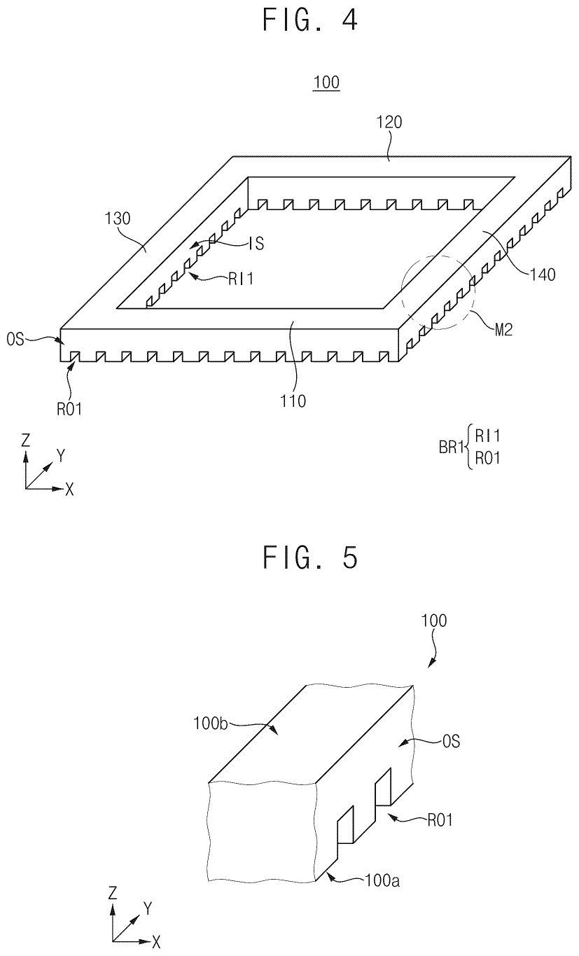

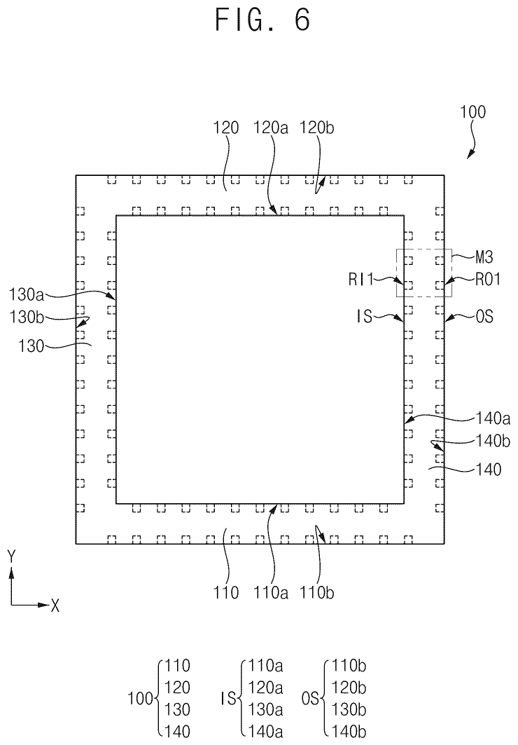

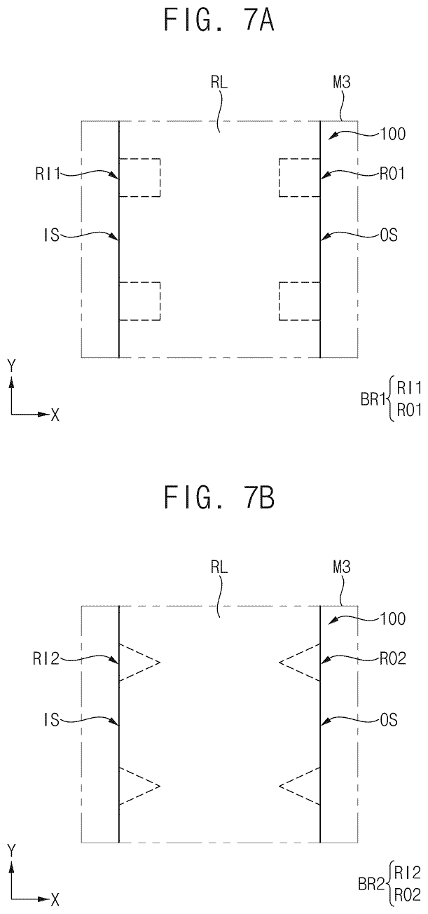

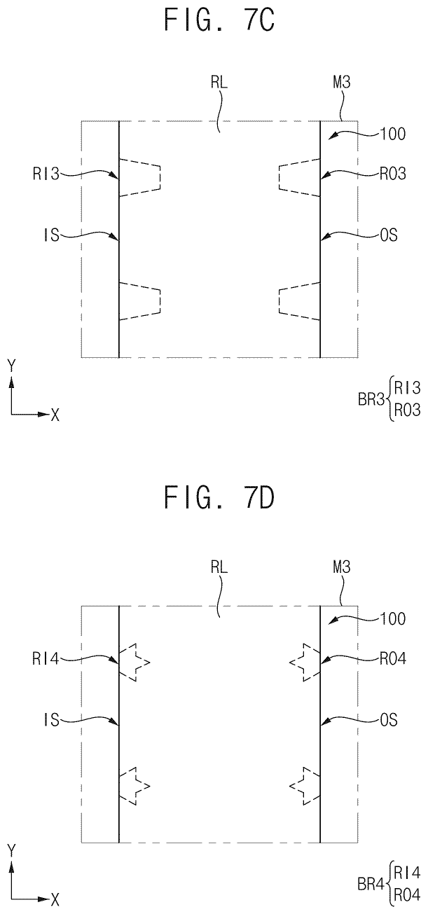

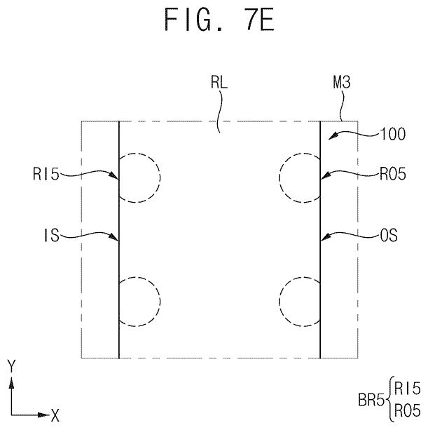

FIG. 1 is a cross-sectional view illustrating a semiconductor package in accordance with example embodiments. FIG. 2 is a plan view illustrating the semiconductor package of FIG. 1. FIG. 3 is an enlarged cross-sectional view illustrating portion ‘M1’ in FIG. 2. FIG. 4 is a perspective view illustrating a stiffener in accordance with example embodiments. FIG. 5 is an enlarged view illustrating portion ‘M2’ in FIG. 4. FIG. 6 is a plan view illustrating the stiffener in FIG. 1. FIG. 7A is an enlarged view illustrating portion ‘M3’ in FIG. 6.

Referring to FIGS. 1 to 7A, a semiconductor package 10 may include a package substrate 21, an interposer 30 mounted on the package substrate 21, a first semiconductor device 40 and a second semiconductor device 50 mounted on the interposer 30, a first stiffener 100 horizontally spaced apart from the interposer 30 on the package substrate 21, and an adhesive member 200 provided between the package substrate 21 and the first stiffener 100. The semiconductor package 10 may further include a plurality of external connection members 25 and a plurality of first conductive connection members 35, a plurality of second conductive connection members 45, and a plurality of third conductive connection members 55. Additionally, the semiconductor package 10 may further include first underfill members 36, second underfill member 46, and third underfill members 56.

For example, the semiconductor package may be a 2.5D package in which the package substrate and semiconductor devices are electrically connected via an interposer. However, example embodiments are not limited thereto, and the number, size, structure, etc. of the semiconductor devices may be varied. Also, the number, size, structure, etc. of interposers may be varied.

In example embodiments, the package substrate 21 may have a first surface 21a and a second surface 21b facing each other. The first surface 21a and second surface 21b may extend in a first horizontal direction (e.g., an X direction) and a second horizontal direction (e.g., a Y direction) perpendicular to the first horizontal direction. For example, the package substrate 21 may have a rectangular shape, when viewed in plan view.

The package substrate 21 may have a first side surface S1 and a second side surface S2 extending in the first horizontal direction and facing each other, and a third side surface S3 and a fourth side surface S4 extending in the second horizontal direction and facing each other.

The package substrate 21 may include a mounting region MR at a central region thereof and an edge region ER surrounding the mounting region MR. For example, the mounting region may have a rectangular shape when viewed in plan view. The mounting region may be an area in which semiconductor devices or interposers are mounted, as will be described later.

The package substrate 21 may include a plurality of first substrate pads 22 arranged on the first surface 21a such that each of the plurality of first substrate pads 22 is at least partially exposed from the first surface 21a, and a plurality of second substrate pads 24 arranged on the second surface 21b such that each of the plurality of second substrate pads 24 is at least partially exposed form the second surface 21b. For example, the plurality of first substrate pads 22 may be provided within the mounting region MR.

The package substrate 21 may include the plurality of external connection members 25 that are respectively provided on the plurality of second substrate pads 24. For example, the external connection members may be structures for electrically connecting the semiconductor package to an external device, such as a printed circuit board (PCB) or the like.

For example, the plurality of first substrate pads 22, the plurality of second substrate pads 24, and the plurality of external connection members 25 may include metallic materials such as copper (Cu), aluminum (Al), nickel (Ni), etc., to transmit electrical signals.

The package board may include a plurality of internal wirings therein. The plurality of internal wirings may be provided within the package substrate to electrically connect the plurality of first substrate pads, the plurality of second substrate pads, and the plurality of external connection members. Although only a few substrate pads are illustrated in the figures, it will be understood that the number, shape, and arrangement of the substrate pads are provided as an example, and example embodiments are not limited thereto.

In example embodiments, the interposer 30 may include an interposer substrate 31 having a first surface 31a and a second surface 31b facing each other, a plurality of first interposer pads 32 arranged on the first surface 31a, a plurality of second interposer pads 34 arranged on the second surface 31b, and the plurality of first conductive connection members 35 arranged respectively on the plurality of second interposer pads 34. The interposer 30 may further include the first underfill member 36 provided on a second surface 31b to cover the plurality of first conductive connection members 35. The interposer 30 may be a structure for efficiently transmitting electrical signals between the package substrate and the semiconductor device. For example, the interposer 30 may be a silicon interposer or a redistribution wiring interposer including a plurality of internal wiring.

The interposer 30 may be mounted on the mounting region MR of the package substrate 21. For example, the interposer 30 may be mounted on the package substrate 21 via the plurality of first conductive connection members 35 each provided between the plurality of first substrate pads 22 and the plurality of second interposer pads 34.

The interposer 30 may be mounted on the mounting region MR such that the second surface 31b of the interposer 30 faces the first surface 21a of the package substrate 21. For example, the first surface may be an active surface, on which circuits are formed, and the second surface may be an inactive surface.

For example, the plurality of first interposer pads 32, the plurality of second interposer pads 34, and the plurality of first conductive connection members 35 may include a metallic material such as copper (Cu), aluminum (Al), nickel (Ni), or the like to transmit electrical signals.

Although internal wiring is not illustrated in the drawings, the interposer substrate 31 may include a plurality of internal wirings. The plurality of internal wirings may be provided within the interposer substrate 31 to electrically connect the plurality of first interposer pads 32, the plurality of second interposer pads 34, and the plurality of first conductive connection members 35. While only a few interposer pads are illustrated in the drawings, it will be understood that the number, shape, and arrangement of the interposer pads are provided as an example, and example embodiments are not limited thereto.

In example embodiments, the first semiconductor device 40 may include a first substrate 41 having a first surface 41a and a second surface 41b facing each other, a plurality of first semiconductor pads 42 arranged on the first surface 41a, and a plurality of second conductive connection members 45 each arranged on the plurality of first semiconductor pads 42. The first semiconductor device 40 may further include the second underfill member 46 provided on the first surface 41a to cover the plurality of second conductive connection members 45.

The first semiconductor device 40 may be mounted on the interposer 30. For example, the first semiconductor device 40 may be mounted on the interposer 30 via the plurality of second conductive connection members 45 provided between the plurality of first interposer pads 32 and the plurality of first semiconductor pads 42, respectively.

The first semiconductor device 40 may be mounted on the mounting region MR such that the first surface 41a of the first semiconductor device 40 faces the first surface 31a of the interposer 30. For example, the first surface of the first semiconductor device may be an active surface, on which circuits are formed, and the second surface of the first semiconductor device may be an inactive surface.

For example, the plurality of first semiconductor pads 42 and the plurality of second conductive connection members 45 may include a metallic material such as copper (Cu), aluminum (Al), nickel (Ni), or the like to transmit electrical signals.

In example embodiments, the second semiconductor device 50 may include a second substrate 51 having a first surface 51a and a second surface 51b facing each other, a plurality of second semiconductor pads 52 arranged on the first surface 51a, and a plurality of third conductive connection members 55 arranged on each of the plurality of second semiconductor pads 52. The second semiconductor device 50 may further include the third underfill member 56 provided on the first surface 51a to cover the plurality of third conductive connection members 55.

The second semiconductor device 50 may be mounted on the interposer 30 to be spaced apart from the first semiconductor device 40 in the first horizontal direction. For example, the second semiconductor device 50 may be mounted on the interposer 30 via the plurality of third conductive connection members 55 provided between the plurality of first interposer pads 32 and the plurality of second semiconductor pads 52, respectively.

The second semiconductor device 50 may be mounted on the mounting region MR such that the first surface 51a of the second semiconductor device 50 faces the first surface 31a of the interposer 30. For example, the first surface 51a of the second semiconductor device 50 may be an active surface, on which circuits are formed, and the second surface 51b of the second semiconductor device 50 may be an inactive surface.

For example, the plurality of second semiconductor pads 52, and the plurality of third conductive connection members 55 may include metallic materials such as copper (Cu), aluminum (Al), nickel (Ni), or the like to transmit electrical signals.

Although only a few semiconductor pads are illustrated in the drawings, it will be understood that the number, shape, and arrangement of the semiconductor pads are provided as an example, and example embodiments are not limited thereto.

Each of the first and second semiconductor devices 40, 50 may be a single semiconductor chip or a semiconductor package including a plurality of semiconductor chips. For example, in some example embodiments, the semiconductor chip may include a logic chip having logic circuitry. In some example embodiments, the semiconductor chip may include a volatile memory device such as DRAM or a non-volatile memory device such as NAND flash memory.

While the drawings illustrate the semiconductor package as a 2.5D package including the first semiconductor device, the second semiconductor device, and the interposer, it will be appreciated that example embodiments are not limited thereto. Accordingly, the arrangement, number, etc. of semiconductor devices included in the semiconductor package may be varied.

In example embodiments, the first stiffener 100 may be provided on the edge region ER of the package substrate 21 to be horizontally spaced from the interposer 30, the first semiconductor device 40, and the second semiconductor device 50.

The first stiffener 100 may include a reinforcement rod RL configured to prevent warpage of the package substrate 21 and a plurality of first adhesive receiving grooves BR1 provided in a lower edge of the reinforcement rod RL to be exposed from both side portions of the reinforcement rod RL (see, e.g., FIG. 3). In some example embodiments, the reinforcement rod RL may reinforce the package substrate 21. For example, the reinforcement rod may include a metallic material such as copper (Cu), aluminum (Al), nickel (Ni), or the like.

The first stiffener 100 may include a first surface 100a and a second surface 100b facing each other. The first stiffener 100 may be provided on the edge region ER of the package substrate 21 such that the first surface 100a of the first stiffener 100 faces the package substrate 21. For example, the first surface 100a of the first stiffener 100 may be a lower surface of the reinforcement rod, and the second surface 100b of the first stiffener 100 may be an upper surface of the reinforcement rod.

The first stiffener 100 may include an inner surface IS and an outer surface OS that face each other and extend between the first surface 100a and the second surface 100b. The inner surface IS may face the interposer 30, the first semiconductor device 40, and the second semiconductor device 50, and the outer surface OS may face the outside of the semiconductor package 10. For example, the first stiffener 100 may be provided on the edge region ER of the package substrate 21 to extend along the side portions S1, S2, S3, S4 of the package substrate 21 and surround the interposer 30, the first semiconductor device 40, and the second semiconductor device 50.

The first stiffener 100 may include a first extension portion 110 and a second extension portion 120 each extending in the first horizontal direction. The first stiffener 100 may include a third extension portion 130 and a fourth extension portion 140 each extending in the second horizontal direction. In some example embodiments, the third and fourth extension portions 130, 140 may connect ends of the first and second extension portions 110, 120 to form a square in plan view.

The first extension portion 110 may have an inner surface 110a and an outer surface 110b facing each other, the second extension portion 120 may have an inner surface 120a and an outer surface 120b facing each other, the third extension portion 130 may have an inner surface 130a and an outer surface 130b facing each other, and the fourth extension portion 140 may have an inner surface 140a and a second surface 140b facing each other. For example, the inner surface 110a of the first extension portion 110, the inner surface 120a of the second extension portion 120, the inner surface 130a of the third extension portion 130, and the inner surface 140a of the fourth extension portion 140 may define the inner surface IS of the first stiffener 100. Further, the outer surface 110b of the first extension portion 110, the outer surface 120b of the second extension portion 120, the outer surface 130b of the third extension portion 130, and the outer surface 140b of the fourth extension portion 140 may define the outer surface OS of the first stiffener 100.

The first stiffener 100 may include a plurality of first adhesive receiving grooves BR1 in the first surface 100a to be exposed from both side portions of the reinforcing rod RL. For example, the plurality of first adhesive receiving grooves may be structures configured to control flow of the adhesive member, as will be described later. The plurality of first adhesive receiving grooves may serve as a buffer space to accommodate the adhesive member.

The plurality of first adhesive recesses BR1 may include a plurality of first inner recesses RI1 arranged along the inner surface IS of the first stiffener 100 and a plurality of first outer recesses RO1 arranged along the outer surface OS of the first stiffener 100. For example, each of the plurality of first inner recesses and each of the plurality of first outer recesses may be provided in a lower edge of the reinforcing rod RL to face each other.

The plurality of first inner recesses RI1 may be formed in the first surface 100a of the first stiffener 100 and the inner surface IS of the first stiffener 100. In other words, the first inner recesses RI1 may extend from the first surface 100a into the first stiffener 100 and may extend from the inner surface IS into the first stiffener 100. The plurality of first outer recesses RO1 may be formed in the first surface 100a of the first stiffener 100 and the outer surface OS of the first stiffener 100. In other words, the first outer recesses RO1 may extend from the first surface 100a into the first stiffener 100 and extend from the outer surface OS into the first stiffener 100.

The first stiffener 100 may include a plurality of inner walls CP provided between the plurality of first inner recesses RI1 and the plurality of first outer recesses RO1, respectively. For example, the inner walls CP may be portions in contact with the adhesive member, as will be described later.

Each of the plurality of first adhesive receiving grooves BR1 may have a rectangular shape, when viewed in plan view. For example, each of the plurality of first adhesive receiving grooves BR1 may have a rectangular shape. However, it will be appreciated that example embodiments are not limited thereto. Accordingly, the shape, size, number, etc. of the plurality of first adhesive receiving grooves may be varied.

In example embodiments, the adhesive member 200 may be provided between the package substrate 21 and the first stiffener 100, to attach the package substrate 21 and the first stiffener 100.

For example, the adhesive member may include a thermosetting epoxy material. The thermosetting epoxy material may be in a fluid state before heat is applied but may harden when heat is applied. Further, the adhesive member may include a filler to improve adhesive performance of the adhesive member. The adhesive member may include a thermal interface material (TIM). The thermal interface material may be a material that enhances thermal conductivity between two mating surfaces by facilitating heat transfer. Specifically, the thermal interface material may be a structure configured to effectively transfer heat between components by closely fitting the components so that there are no microscopic spaces between the components.

The adhesive member 200 may cover the first surface 100a of the first stiffener 100, and the adhesive member 200 may be at least partially received within the plurality of first adhesive receiving grooves BR1 of the first stiffener 100. For example, each of the plurality of inner walls CP of the first stiffener 100 may include a contact region CA in contact with the adhesive member 200 and an exposed region EA that is not in contact with the adhesive member 200 and is exposed to the outside. At least a portion of the adhesive member 200 may be provided on the contact region CA of the stiffener 100.

The adhesive member 200 may include a base portion BP provided on the first surface 100a of the first stiffener 100 and a vertical extension EP extending in a vertical direction (e.g., Z-direction) from the base portion BP.

For example, the adhesive member 200 may be in a fluid state before hardening so that the adhesive member moves from a center portion of the first stiffener 100 towards the plurality of first adhesive receiving grooves BR1 to fill a space between the first surface 100a of the first stiffener 100 and the first surface 21a of the package substrate 21.

A portion EP of the adhesive member may at least partially fill the plurality of first adhesive receiving grooves BR1. For example, a portion of the adhesive member EP may move in the vertical direction partially filling the plurality of first adhesive receiving grooves BR1 by a capillary effect. The capillary effect may be a phenomenon in which a liquid inside a narrow tube moves itself inside the tube due to surface tension of the liquid and adhesion of the liquid to the tube.

The adhesive member 200 may be cured by heat to integrally bond the first stiffener 100 and the package substrate 21 and fill the space between the first surface 100a of the first stiffener 100 and the first surface 21a of the package substrate 21 and a portion of each of the plurality of first adhesive receiving grooves BR1.

Thus, the plurality of first adhesive receiving grooves BR1 may provide a space configured to receive the portion EP of the adhesive member 200, thereby preventing the adhesive member 200 from bleeding from the package substrate 21 to the outside of the packages substrate 21.

Each of the plurality of center portions CP of the first stiffener 100 may have a first width W1, and the base portion BP of the adhesive member 200 may have a second width W2 larger than the first width W1. Thus, the adhesive member 200 may cover the entire first surface 100a of the first stiffener 100, so that the adhesive member 200 may provide sufficient adhesion between the first stiffener 100 and the package substrate 21.

Each of the plurality of first adhesive receiving grooves BR1 of the first stiffener 100 may have a depth D in the vertical direction from the first surface 100a of the first stiffener 100, and the vertical extension EP of the adhesive member 200 may have a height H in the vertical direction from the first surface 100a of the first stiffener 100 that is less than the depth D of the adhesive receiving grooves. For example, in an example embodiment, the height H of the vertical extension EP may be half of the depth D of the adhesive receiving groove. However, it will be appreciated that example embodiments are not limited thereto. Accordingly, the shape, size, structure, arrangement, etc. of the vertical extension may be varied.

For example, the depth D of the adhesive receiving groove may be less than a height in the vertical direction of the first stiffener 100. For example, in an example embodiment, the height in the vertical direction of the first stiffener 100 may be within a range of about 0.7 mm to about 3.0 mm. Further, the depth D of the adhesive receiving groove may be greater than the size of a filler included in the adhesive member 200. For example, in an example embodiment, the size of the filler may be within a range of about 20 μm to about 100 μm. However, it will be appreciated that example embodiments are not limited thereto. Accordingly, the shape, size, structure, arrangement, etc. of the adhesive receiving groove may be varied.

FIGS. 7B to 7E are enlarged views illustrating various shapes of adhesive receiving grooves in accordance to example embodiments.

Referring to FIG. 7B, the plurality of second adhesive recesses BR2 may include a plurality of second inner recesses RI2 and a plurality of second outer recesses RO2. For example, the second inner recess RI2 and the second outer recess RO2 may have a triangular shape, when viewed in plan view.

Referring to FIG. 7C, the plurality of third adhesive receiving grooves BR3 may include a plurality of third inner recesses RI3 and a plurality of third outer recesses RO3. For example, the third inner recess RI3 and the third outer recess RO3 may have a trapezoidal shape, when viewed in plan view.

Referring to FIG. 7D, the plurality of fourth adhesive receiving grooves BR4 may include a plurality of fourth inner recesses RI4 and a plurality of fourth outer recesses RO4. For example, the fourth inner recess RI4 and the fourth outer recess RO4 may have the shape of a polygon, when viewed in plan view. For example, the polygon may be a shape including a plurality of triangles.

Referring to FIG. 7E, the plurality of fifth adhesive receiving grooves BR5 may include a plurality of fifth inner recesses RI5 and a plurality of fifth outer recesses RO5. For example, the fifth inner recess RI5 and the fifth outer recess RO5 may have a circular shape, when viewed in plan view.

However, it will be appreciated that example embodiments are not limited thereto. Accordingly, the shape, size, number, structure, arrangement, etc. of the plurality of adhesive receiving grooves may be varied.

As described above, the semiconductor package 10 may include the package substrate 21 having the mounting region MR and the edge region ER surrounding the mounting region MR, and at least one semiconductor device mounted on the mounting region MR of the package substrate 21, the first stiffener 100 provided on the edge region ER of the package substrate 21, and the adhesive member 200 provided between the package substrate 21 and the first stiffener 100 to attach the package substrate 21 and the first stiffener 100.

The first stiffener may include the reinforcement rod RL configured to prevent warpage of the package substrate 21 by reinforcing the package substrate 21 and the plurality of first adhesive receiving grooves BR1 exposed from both side portions of the reinforcing rod RL and provided in the lower edge of the reinforcement rod RL.

Accordingly, the plurality of first adhesive receiving grooves BR1 may prevent the adhesive member 200 from overflowing from the package substrate 21 to the outside of the package substrate 21. Furthermore, since the plurality of first adhesive receiving grooves BR1 are provided in the edges of the reinforcing rod RL, the plurality of first adhesive receiving grooves BR1 can help the adhesive member 200 sufficiently cover the space between the first stiffener 100 and the package substrate 21. In addition, the first stiffener 100 may prevent warpage of the package substrate 21.

The plurality of first adhesive receiving grooves BR1 may have a shape that is circular, triangular, square, or polygonal when viewed in plan view.

Accordingly, the shape may increase a contact region between uncured adhesive member 200 and the inner surface RI1 of the first adhesive receiving groove BR1, thereby enhancing the capillary phenomenon of the uncured adhesive member 200 moving along the plurality of first adhesive receiving grooves BR1, thereby effectively preventing the uncured adhesive member 200 from overflowing from the package substrate 21 to the outside of the package substrate.

Hereinafter, a method of manufacturing the semiconductor package 10 of FIG. 1 will be described.

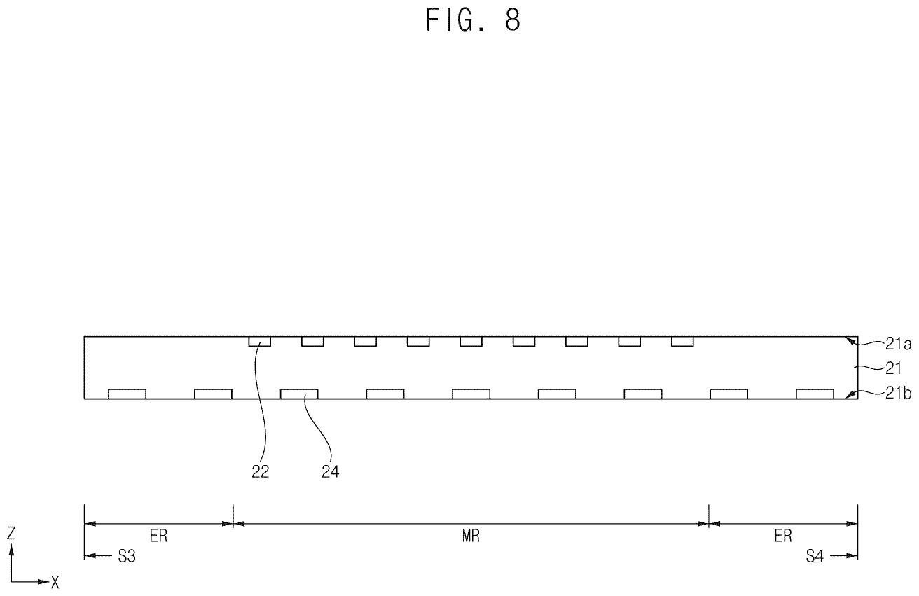

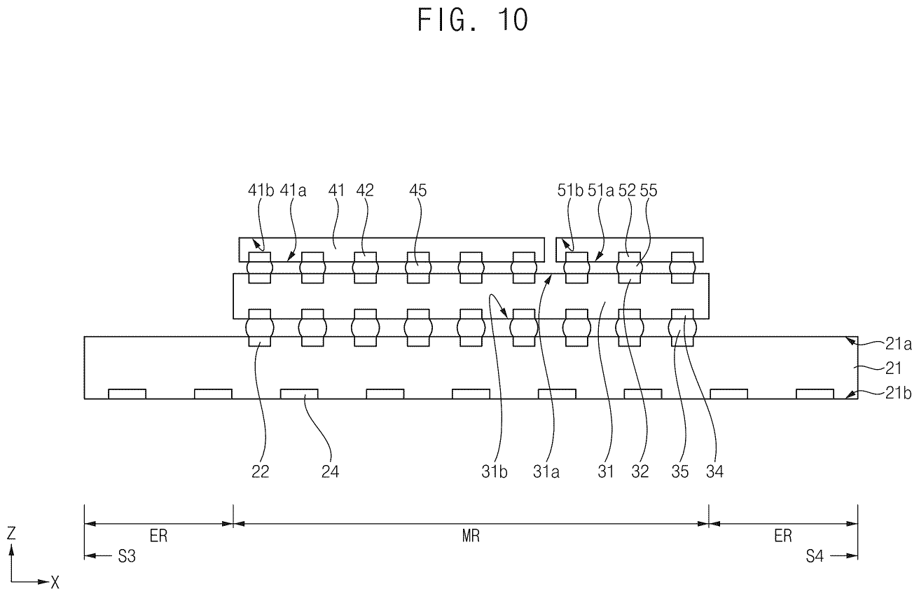

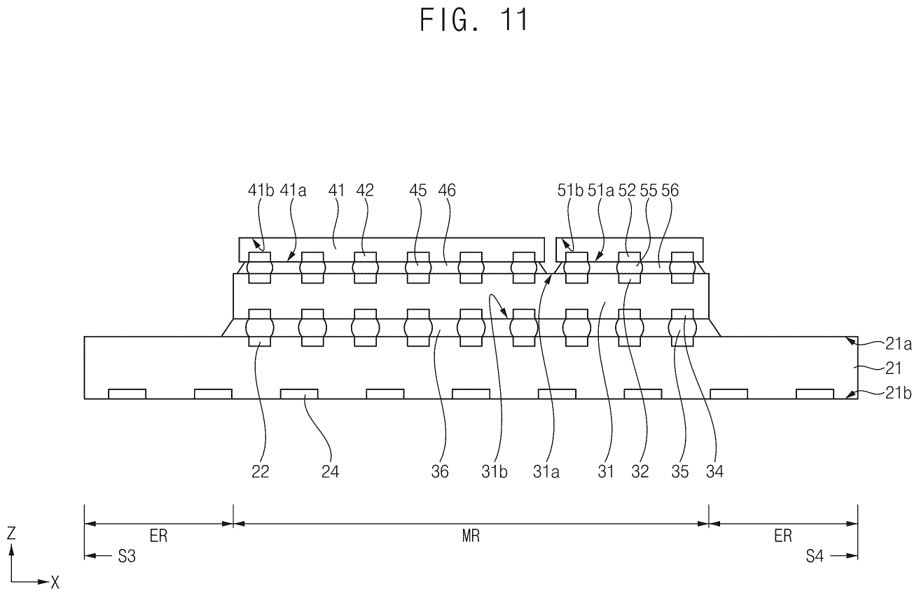

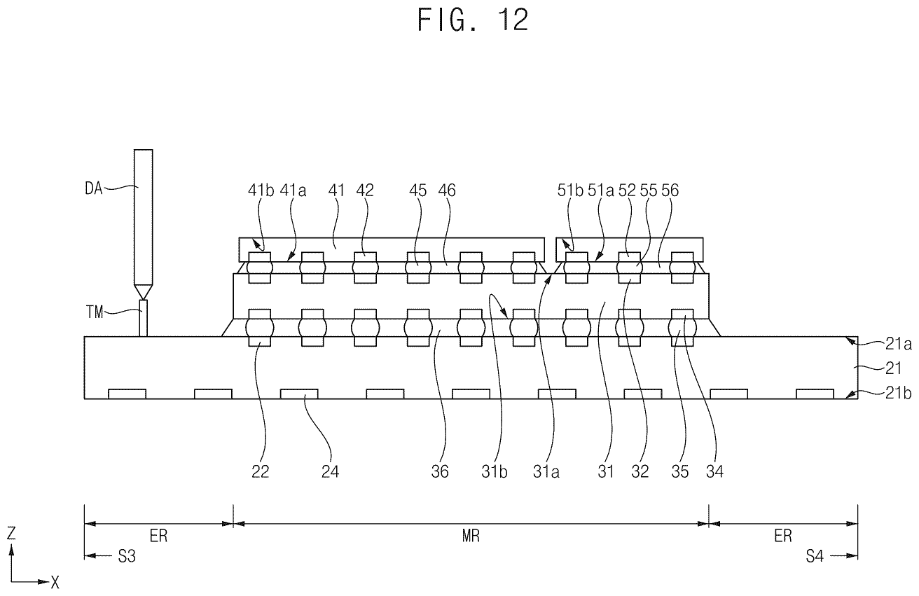

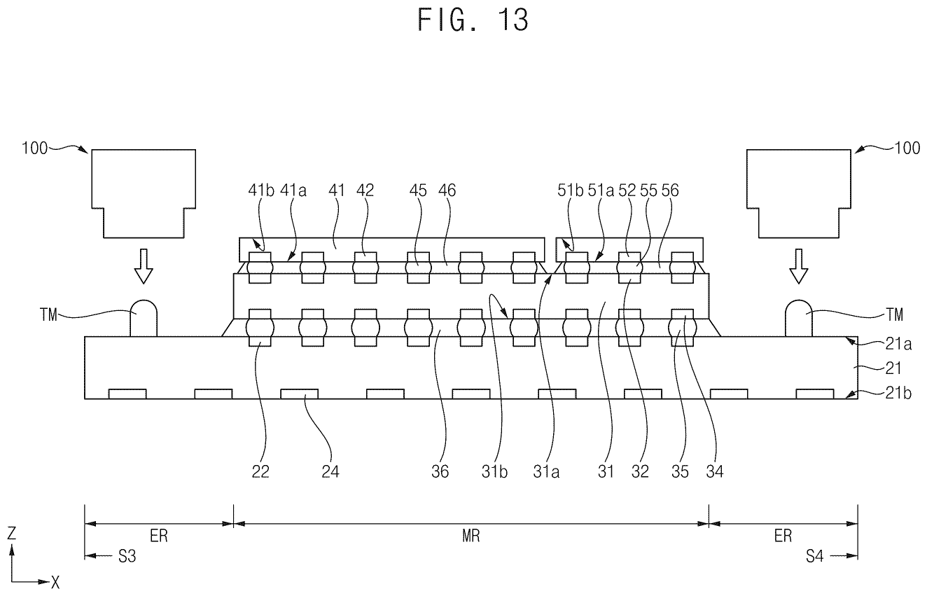

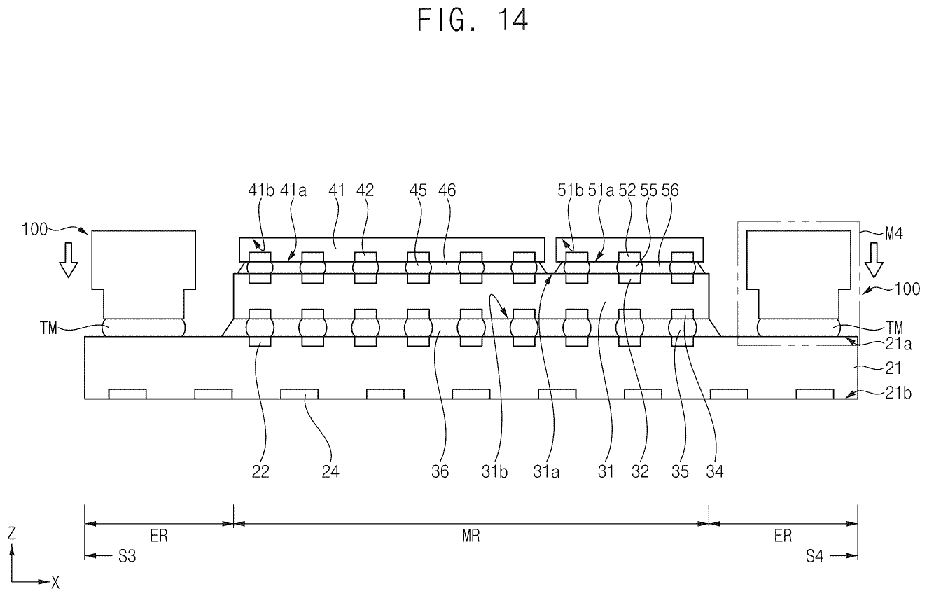

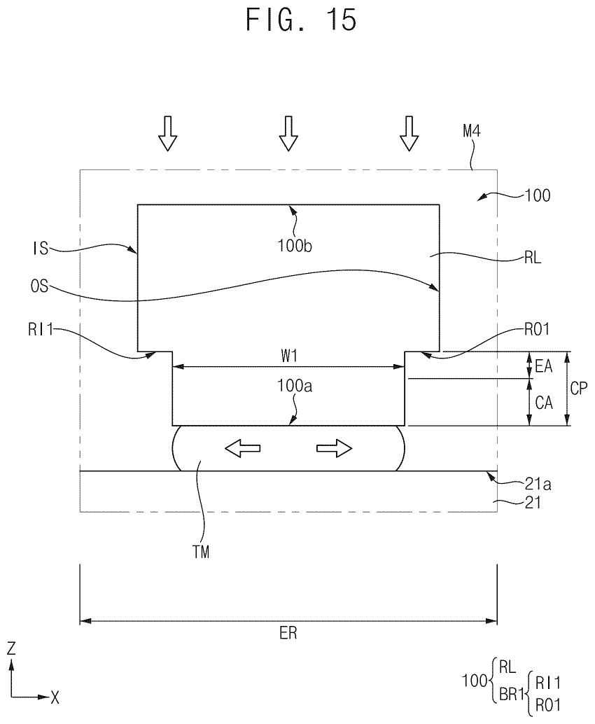

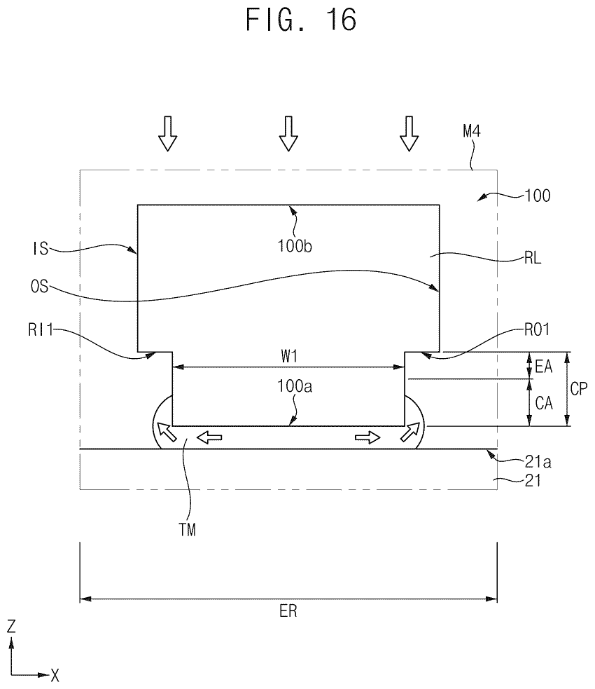

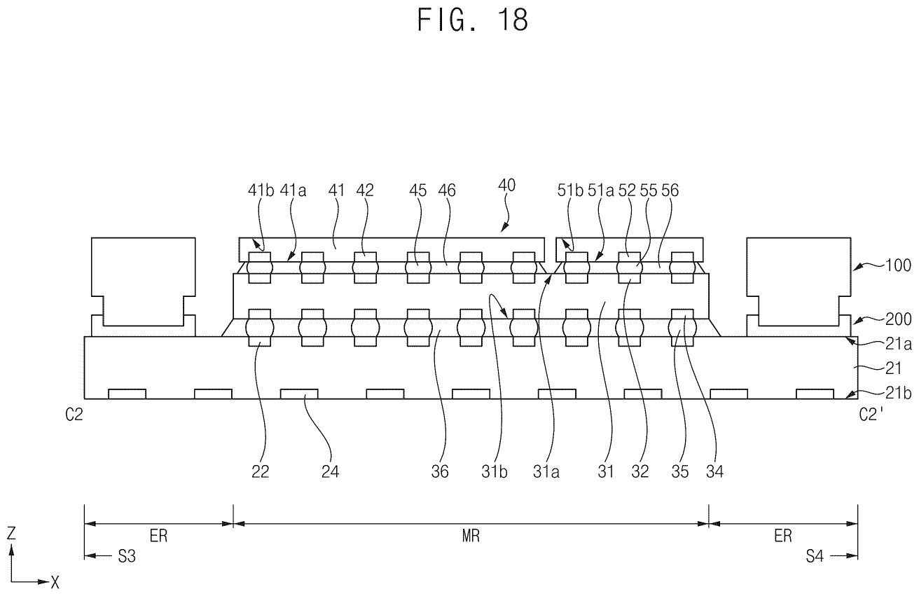

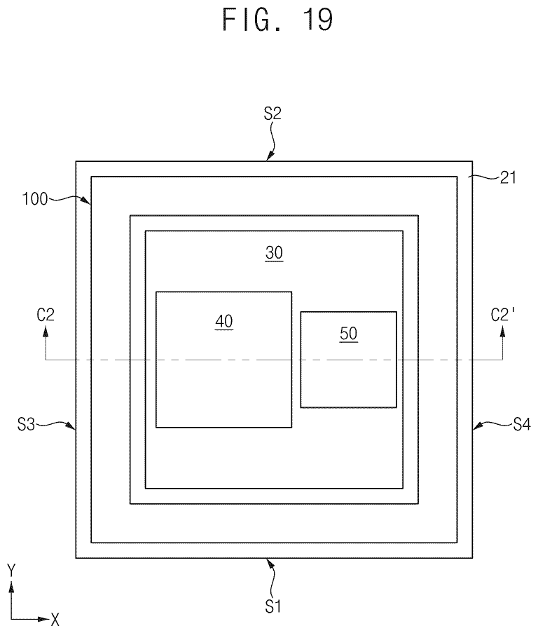

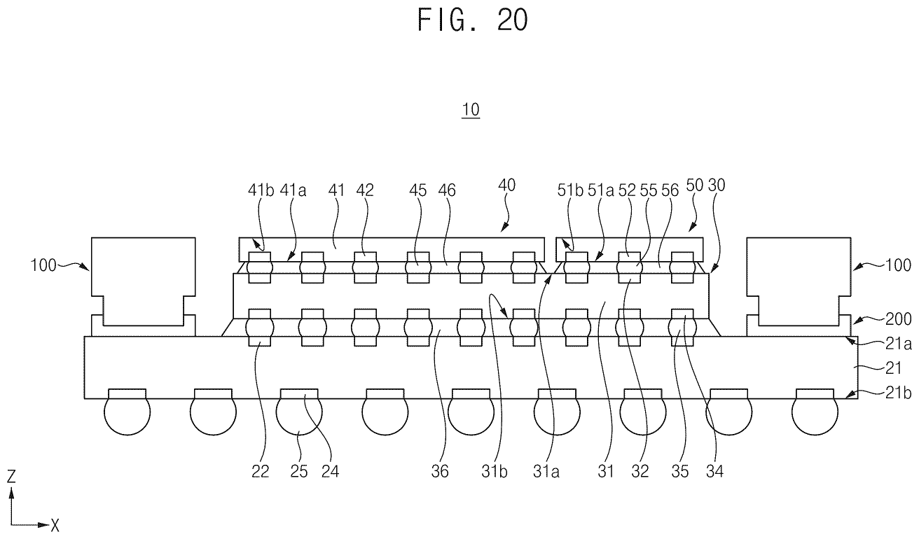

FIGS. 8 to 11 are views illustrating process of mounting semiconductor devices on a package substrate. FIG. 12 is a view illustrating a process of applying an adhesive material to the package substrate in FIG. 11. FIGS. 13 to 19 are views illustrating processes of attaching a stiffener to the package substrate via the adhesive member in FIG. 12. FIGS. 14 to 16 are enlarged cross-sectional views illustrating portion ‘M4’ in FIG. 13. FIG. 18 is a cross-sectional view taken along the line C2-C2′ in FIG. 19. FIG. 20 is a view illustrating a process of attaching external connection members to the package substrate in FIG. 18.

Since the semiconductor package manufactured by the manufacturing process illustrated in FIGS. 8 to 20 is substantially identical to the semiconductor package described in FIGS. 1 to 7E, identical components are denoted by the same reference numerals, and repeated descriptions of identical components are omitted for conciseness.

Referring to FIGS. 8 to 11, an interposer 30 may be mounted on the mounting region MR of the package substrate 21, and the first semiconductor device 40 and the second semiconductor device 50 may be mounted on the interposer 30.

For example, the interposer 30 may be stacked on the mounting region MR of the package substrate 21, and the package substrate 21 and the interposer 30 may be electrically connected via the plurality of first conductive connection members 35 by applying heat to the plurality of first conductive connection members 35. For example, the plurality of first conductive connection members 35 may be heated to melt and then cooled to solidify again through a reflow process.

Then, the first semiconductor device 40 and the second semiconductor device 50 may be stacked on the interposer 30 to be horizontally spaced apart from each other, and the plurality of second conductive connection members 45 may be heated to electrically connect the interposer 30 and the first semiconductor device 40 via the plurality of second conductive connection members 45, and the plurality of third conductive connection members 55 may be heated to electrically connect the interposer 30 and the second semiconductor device 50 via the plurality of third conductive connection members 55. For example, through a reflow process, the plurality of second conductive connection members 45 and the plurality of third conductive connection members 55 may each be heated to melt and then cooled to solidify again.

Then, an underfill material may be injected between the package substrate 21 and the interposer 30 to cover the plurality of first conductive connection members 35, and the underfill material may be injected between the interposer 30 and the first semiconductor device 40 to cover the plurality of second conductive connection members 45, and the underfill material may be injected between the interposer 30 and the second semiconductor device 50 to cover the plurality of third conductive connection members 55. The underfill material may then be cured to form a first underfill member 36 configured to secure the package substrate 21 and the interposer 30, a second underfill member 46 configured to secure the interposer 30 and the first semiconductor device 40, and a third underfill member 56 configured to secure the interposer 30 and the second semiconductor device 50.

Referring to FIGS. 12 to 19, an adhesive material TM may be applied to an edge region ER of the package substrate 21, a first stiffener 100 may be positioned on the adhesive material TM, and the adhesive material TM may be heated while applying pressure to the first stiffener 100 to attach the first stiffener 100 to the package substrate 21 via the adhesive member 200.

In example embodiments, the first stiffener 100 may have a first surface 100a and a second surface 100b facing each other. The first stiffener 100 may have an inner surface IS and an outer surface OS facing each other and extending through the first surface 100a and the second surface 100b.

The first stiffener 100 may include a reinforcement rod RL configured to prevent warpage of the package substrate 21 and a plurality of first adhesive receiving grooves BR1 exposed from both side portions of the reinforcement rod RL and formed on a lower edge of the reinforcement rod RL. For example, the reinforcement rod may include a metallic material such as copper (Cu), aluminum (Al), nickel (Ni), or the like. Further, the first stiffener 100 may include a first extension portion 110 and a second extension portion 120 each extending in the first horizontal direction, and a third extension portion 130 and a fourth extension portion 140 each extending in the second horizontal direction.

The first stiffener 100 may include a plurality of first adhesive receiving grooves BR1 on the first face 100a exposed from both side portions of the reinforcement rod RL. For example, the plurality of first adhesive receiving grooves may be formed using a laser grooving process, a casting process, or the like. The laser grooving process may be a process in which light is irradiated to remove certain materials. The casting process may be a process of making a mold in the shape of the product, filling the mold with liquid metal, and cooling the metal to form the product.

The plurality of first adhesive receiving grooves BR1 may include a plurality of first inner recesses RI1 arranged along the inner surface IS of the first stiffener 100 and a plurality of first outer recesses RO1 arranged along the outer surface OS of the first stiffener 100. For example, the first inner recess and the first outer recess may be provided on each side portion of the first stiffener 100 to face each other.

The first stiffener 100 may include a plurality of inner walls CP each provided between the plurality of first inner recesses RI1 and the plurality of first outer recesses RO1.

The plurality of first inner recesses RI1 may be exposed from the first surface 100a of the first stiffener 100 and the inner surface IS of the first stiffener 100. A plurality of first outer recesses RO1 may be exposed from the first surface 100a of the first stiffener 100 and the outer surface OS of the first stiffener 100.

An adhesive material TM may be applied to the edge region ER of the package substrate 21, and the first stiffener 100 may be positioned on the applied adhesive material. The first stiffener 100 may be positioned on the edge region ER of the package substrate 21 such that a plurality of first adhesive receiving grooves BR1 of the first stiffener 100 face the package substrate 21. For example, the adhesive material TM may be fluid since the adhesive material has low viscosity.

For example, the adhesive material TM may include a thermosetting epoxy material. The thermosetting epoxy material may be in a fluid state before heat is applied but may cure and solidify when exposed to heat. Further, the adhesive member 200 may include a filler to improve adhesive performance of the adhesive member. The adhesive member 200 may include a thermal interface material (TIM). The thermal interface material may be a material that enhances thermal conductivity between two mating surfaces by facilitating heat transfer. Specifically, the thermal interface material may be a structure configured to effectively transfer heat between the components by closely fitting the components so that there are no microscopic spaces between the components.

Then, the adhesive material TM may be heated to cure while moving the first stiffener 100 in the vertical direction toward the package substrate 21. Since the adhesive material is fluid, the adhesive material may fill void between the first stiffener 100 and the package substrate 21, and then the adhesive material may be cured to integrally bond the first stiffener 100 and the package substrate 21.

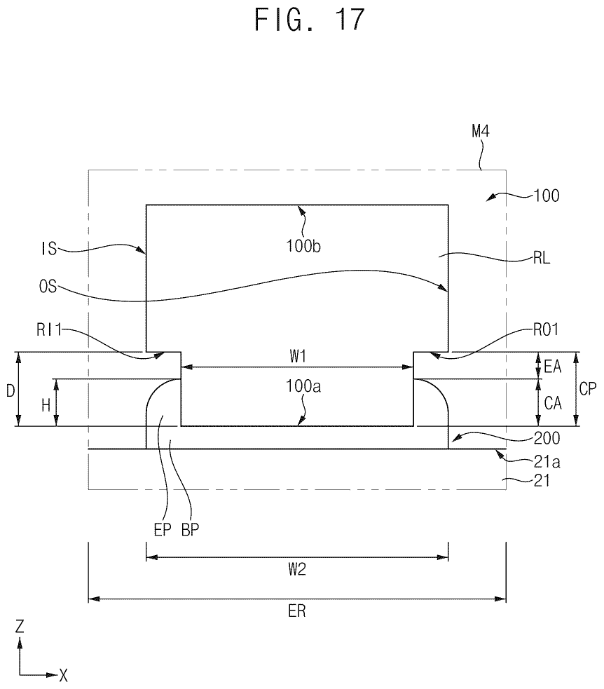

Referring again to FIGS. 15 to 17, the adhesive material TM may move in a horizontal direction while the first stiffener 100 moves downwardly on the package substrate 21. For example, the adhesive material may move from a center portion of the first stiffener 100 toward the plurality of first adhesive receiving grooves BR1 to at least partially fill space between the first surface 100a of the stiffener 100 and the first surface 21a of the package substrate 21.

Thereafter, a portion of the adhesive material may move in the vertical direction along the plurality of first adhesive receiving grooves BR1 to at least partially fill each of the plurality of first adhesive receiving grooves BR1. For example, each of the plurality of first adhesive receiving grooves BR1 may have a predetermined depth D. For example, the adhesive material may fill half of the depth D of the adhesive receiving groove.

For example, a portion of the adhesive material may move in the vertical direction to at least partially fill the plurality of first adhesive receiving grooves BR1 by a capillary effect. The capillary effect may be a phenomenon in which a liquid inside a narrow tube moves itself inside the tube due to the surface tension of the liquid and the adhesion force of the liquid to the tube.

Thus, after the adhesive material covers the first surface 100a of the first stiffener 100, a remaining portion of the adhesive material can be received in the plurality of first adhesive receiving grooves BR1. Thus, the plurality of first adhesive receiving grooves BR1 may act as a buffer space to prevent bleeding of the adhesive material from the package substrate 21 to the outside.

The adhesive material may be cured by heat to form an adhesive member 200 configured to secure the first stiffener 100 and the package substrate 21.

Thus, the adhesive member 200 may cover all of the first surface 100a of the first stiffener 100, and thus, the adhesive member may provide sufficient adhesion between the first stiffener 100 and the package substrate 21.

Referring to FIG. 20, a plurality of external connection members 25 may be attached to the plurality of second substrate pads 24 of the package substrate 21, thereby completing the semiconductor package 10.

While only a single package substrate 21 is illustrated in the figures, it will be appreciated that example embodiments are not limited thereto. Thus, the process illustrated in FIGS. 8 to 20 may be performed on a package array including a plurality of package substrates. However, in this case, a cutting process may be added to separate the package array into individual semiconductor packages.

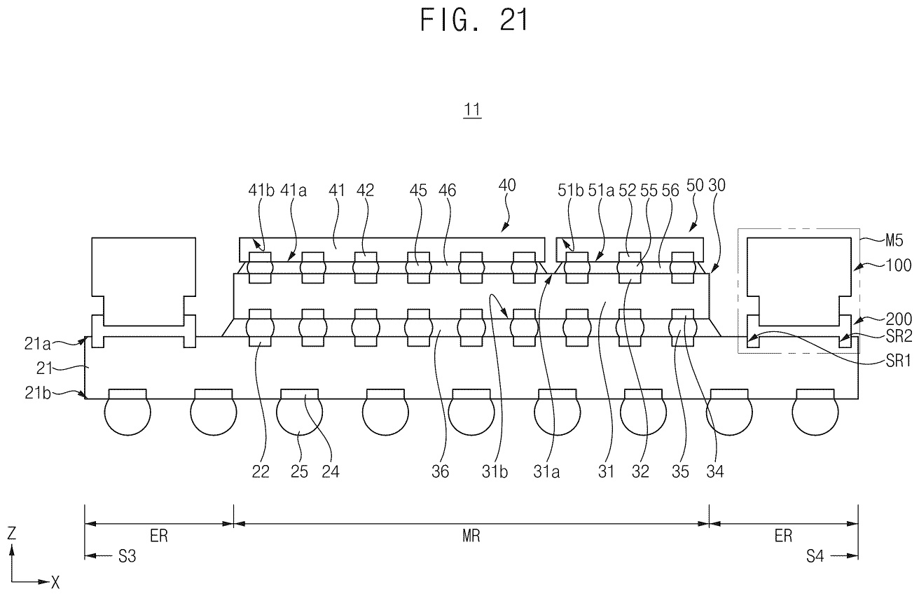

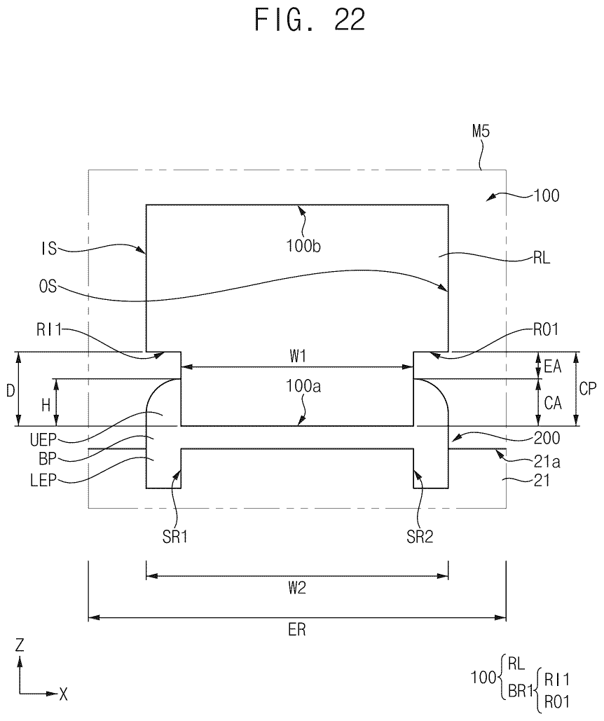

FIG. 21 is a cross-sectional view illustrating a semiconductor package in accordance with example embodiments. FIG. 22 is an enlarged cross-sectional view illustrating the ‘M5’ portion of FIG. 21.

The semiconductor package illustrated in FIGS. 21 and 22 is substantially the same as the semiconductor package described in FIGS. 1 to 7E, except for the package substrate 21 and the adhesive member 200, so identical components are denoted by the same reference numerals, and repeated descriptions of identical components are omitted for conciseness.

Referring to FIGS. 21 and 22, the semiconductor package 11 may include a package substrate 21, an interposer 30 mounted on the package substrate 21, a first semiconductor device 40 and a second semiconductor device 50 mounted on the interposer 30, a first stiffener 100 provided horizontally spaced apart from the interposer 30 on the package substrate 21, and an adhesive member 200 provided between the package substrate 21 and the first stiffener 100.

In example embodiments, the package substrate 21 may include the plurality of first substrate pads 22 arranged on the first surface 21a to be at least partially exposed from the first surface 21a, and the plurality of second substrate pads 24 arranged on the second surface 21b to be at least partially exposed from the second surface 21b. Further, the package substrate 21 may include the plurality of external connection members 25 each provided on the plurality of second substrate pads 24. The package substrate 21 may further include a plurality of first substrate recesses SR1 and a plurality of second substrate recesses SR2.

The package substrate illustrated in FIGS. 21 and 22 is substantially the same as the package substrate described in FIGS. 1 to 7e, except for the plurality of first substrate recesses SR1 and the plurality of second substrate recesses SR2, so that identical components are denoted by the same reference numerals and repeated descriptions of identical components are omitted for conciseness.

The plurality of first substrate recesses SR1 and the plurality of second substrate recesses SR2 may be provided on the edge region ER of the package substrate 21 to surround the mounting region MR of the package substrate 21. For example, the plurality of first substrate recesses and the plurality of second substrate recesses may be structures configured to control flow of the adhesive member 200, thereby preventing the adhesive member 200 from bleeding from the package substrate 21 to the outside. For example, the plurality of first substrate recesses and the plurality of second substrate recesses may act as buffers.

The plurality of first substrate recesses SR1 may be arranged on the edge region ER of the package substrate 21 to be adjacent to the mounting region MR such that the plurality of first substrate recesses SR1 correspond to the plurality of first inner recesses RI1 of the first stiffener 100. The plurality of second substrate recesses SR2 may arranged on the edge region ER of the package substrate 21 to be adjacent to the outer side portions S1, S2, S3, S4 of the package substrate 21 such that the plurality of second substrate recesses SR2 correspond to the plurality of first outer recesses RO1 of the first stiffener 100.

In example embodiments, the adhesive member 200 may at least partially fill space between the first surface 100a of the first stiffener 100 and the first surface 21a of the package substrate 21, the plurality of first substrate recesses SR1 and the plurality of second substrate recesses SR2 of the package substrate 21, and the plurality of first adhesive receiving grooves BR1 of the first stiffener 100.

The adhesive member 200 illustrated in FIGS. 21 and 22 is substantially the same as the adhesive member illustrated in FIGS. 1 to 7e, except that the adhesive member 200 at least partially fill the plurality of first substrate recesses SR1 and the plurality of second substrate recesses SR2, so identical components are denoted by the same reference numerals and repeated descriptions of identical components are omitted for conciseness.

The adhesive member 200 may include a base portion BP extending horizontally between the first stiffener 100 and the package substrate 21, a lower extension portion LEP extending downwardly from the base portion BP, and an upper extension portion UEP extending upwardly from the base portion BP.

As described above, the package substrate 21 of the semiconductor package 11 may further include the plurality of first substrate recesses SR1 and the plurality of second substrate recesses SR2. The plurality of first substrate recesses may be arranged to correspond to a plurality of first inner recesses RI1 of the first stiffener 100, and the plurality of second substrate recesses may be arranged to correspond to a plurality of first outer recesses RO 1 of the first stiffener 100.

Accordingly, the adhesive member 200 can be at least partially received in the plurality of first adhesive receiving grooves BR1, the plurality of first substrate recesses SR1, and the plurality of second substrate recesses SR2 of the first stiffener 100, thereby preventing the adhesive member 200 from overflowing outwardly.

Furthermore, the plurality of first adhesive recesses BR1 may be provided on both side portions of the first stiffener 100, and a plurality of first substrate recesses SR1 and a plurality of second substrate recesses SR2 may be arranged to correspond with the plurality of first adhesive recesses BR1, so the plurality of first adhesive receiving grooves BR1, the plurality of first substrate recesses SR1, and the plurality of second substrate recesses SR2 can help the adhesive member 200 sufficiently cover the space between the first stiffener 100 and the package substrate 21.

Further, since the adhesive member 200 covers the first surface 100a of the first stiffener 100, the adhesive member 200 can provide sufficient adhesion between the first stiffener 100 and the package substrate 21.

Hereinafter, a method of manufacturing the semiconductor package 11 in FIG. 21 will be described.

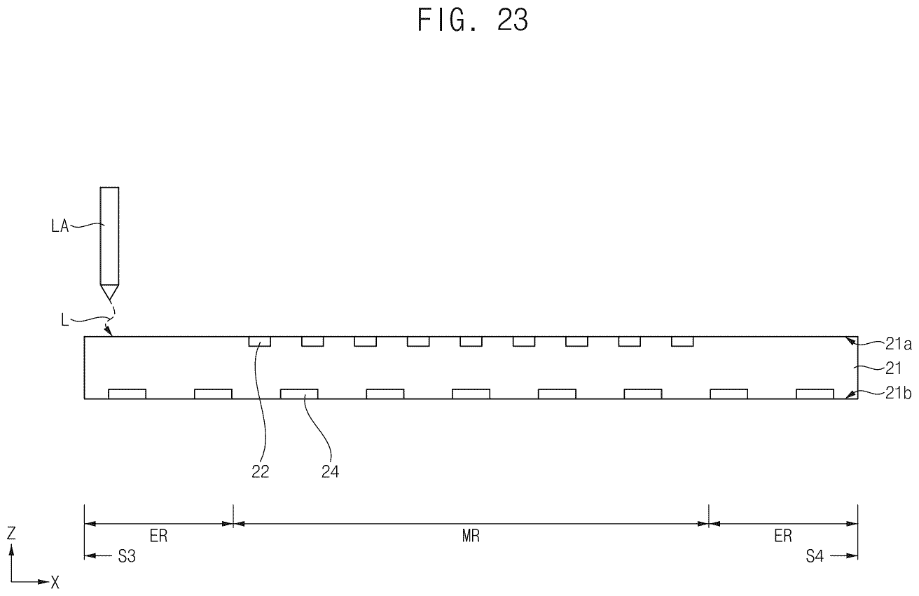

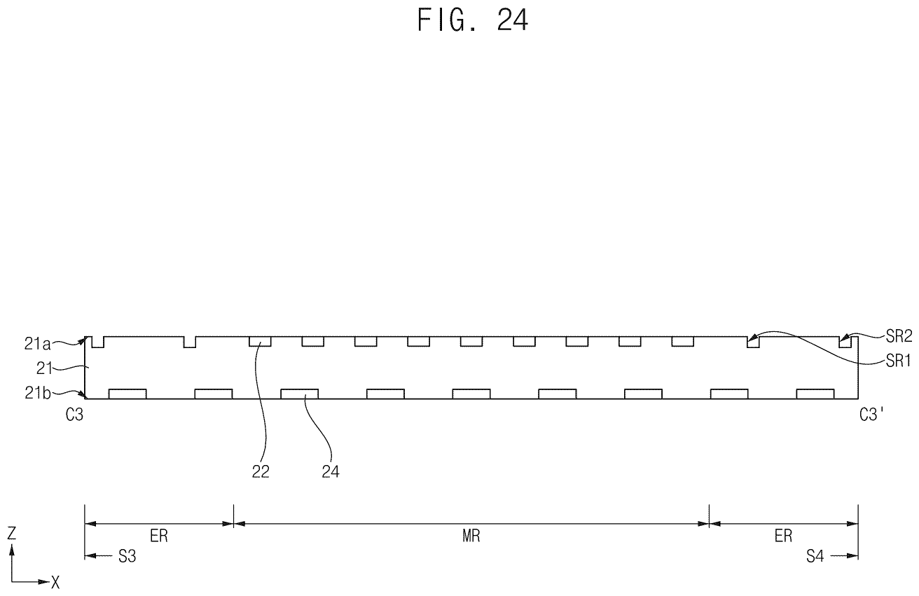

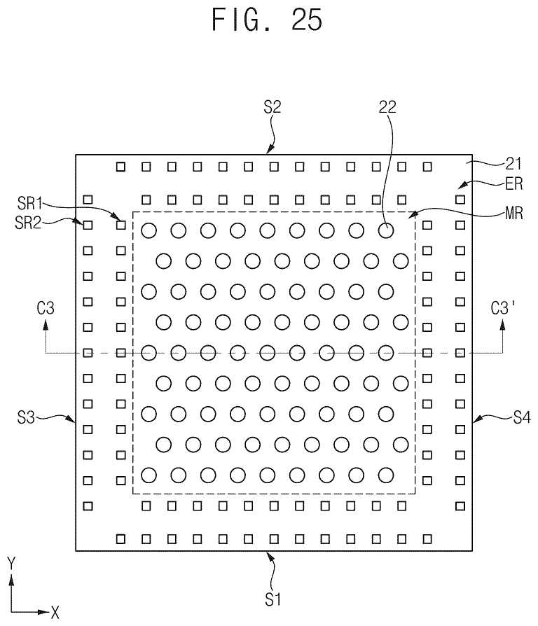

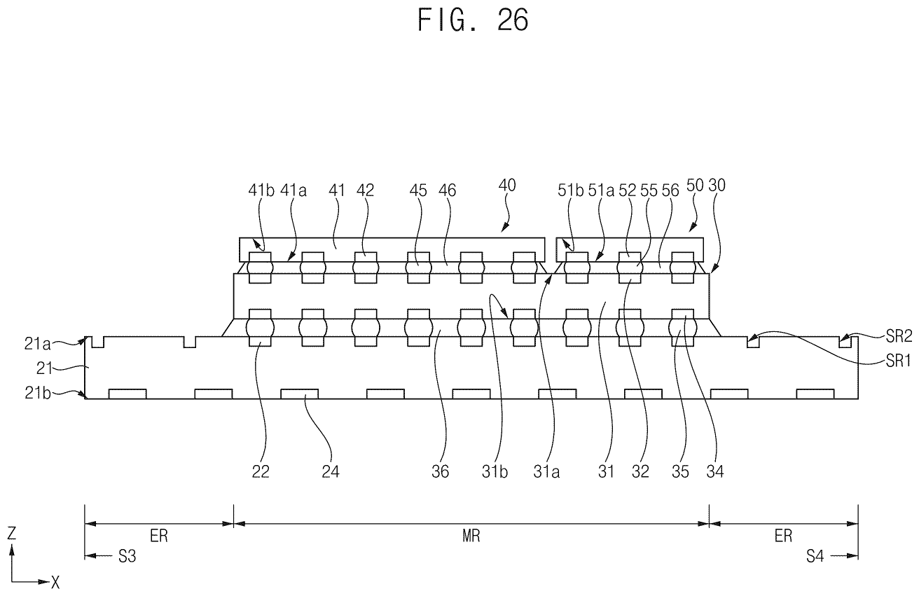

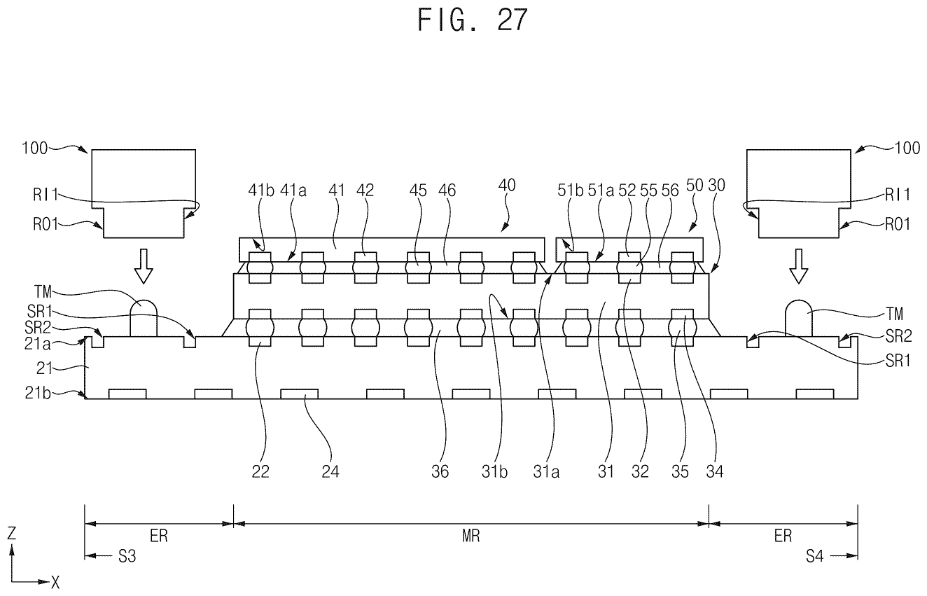

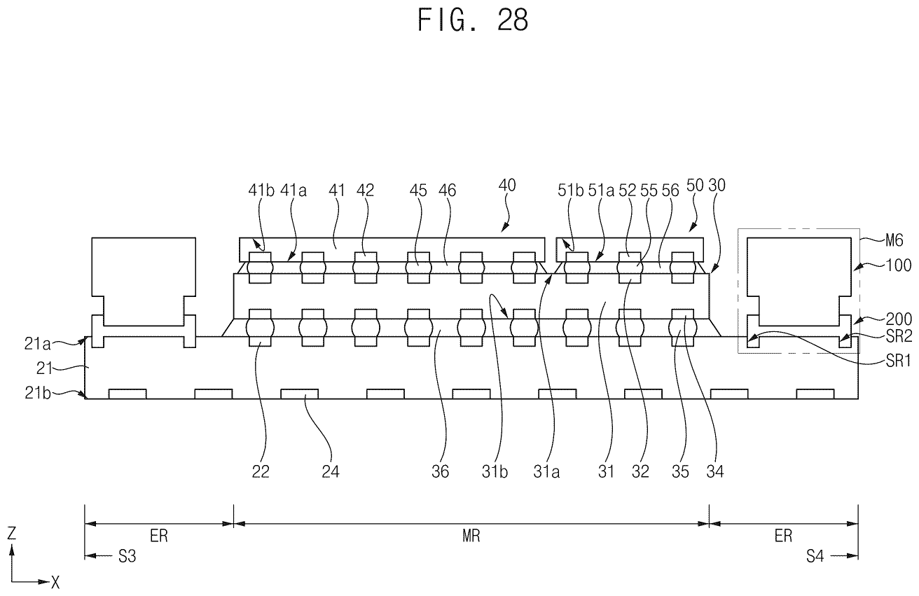

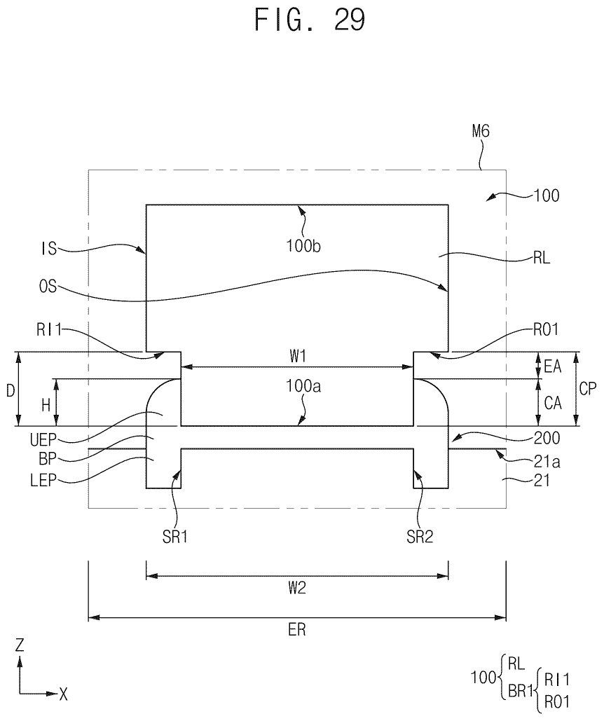

FIGS. 23 to 25 are views illustrating a plurality of substrate recesses being formed on an edge region of a package substrate. FIG. 24 is a cross-sectional view taken along the C3-C3′ line in FIG. 25. FIG. 26 is a view illustrating a semiconductor device being mounted on the package substrate in FIG. 25. FIGS. 27 to 29 are views illustrating a stiffener being attached to the package substrate via an adhesive member. FIG. 29 is an enlarged cross-sectional view illustrating portion ‘M6’ in FIG. 28.

Since the semiconductor package manufactured by the manufacturing process illustrated in FIGS. 23 to 29 is substantially the same as the semiconductor package described in FIGS. 21 and 22, identical components are denoted by the same reference numerals, and repeated descriptions of identical components are omitted for conciseness.

Referring to FIGS. 23 to 25, a package substrate 21 having a mounting region MR and an edge region ER surrounding the mounting region MR may be provided, and a plurality of first substrate recesses SR1 and a plurality of second substrate recesses SR2 may be formed on the edge region ER of the package substrate 21.

In example embodiments, the package substrate 21 may have a first surface 21a and a second surface 21b facing each other. Further, the package substrate 21 may have a first side portion S1 and a second side portion S2 extending in a first horizontal direction (e.g., an X direction) and facing each other, and a third side portion S3 and a fourth side portion S4 extending in a second horizontal direction (e.g., a Y direction) and facing each other.

The package substrate 21 may include a plurality of first substrate pads 22, which are arranged on the first surface 21a to be at least partially exposed from the first surface 21a, and a plurality of second substrate pads 24, which are arranged on the second surface 21b to be at least partially exposed from the second surface 21b. For example, the plurality of first substrate pads 22 may be provided within the mounting region MR. The package substrate 21 may also include a plurality of external connection members 25 each provided on the plurality of second substrate pads 24.

A laser processing device LA may be positioned over an edge region ER of the package substrate 21, and light L from the laser processing device LA may be irradiated to partially remove the package substrate 21 to form a plurality of first substrate recesses SR1 and a plurality of second substrate recesses SR2. For example, the laser processing device LA may be moved in the first horizontal direction or the second horizontal direction along the edge region ER, and the light L may be irradiated repeatedly.

In example embodiments, the plurality of first substrate recesses SR1 and the plurality of second substrate recesses SR2 may be structures configured to control flow of the adhesive member 200 to prevent bleeding of the adhesive member 200 from the package substrate 21 to the outside. For example, the plurality of first substrate recesses SR1 and the plurality of second substrate recesses SR2 may act as buffers.

Referring to FIG. 26, an interposer 30 may be provided on the mounting region MR of the package substrate 21 to mount a first semiconductor device 40 and a second semiconductor device 50 on the interposer 30, respectively.

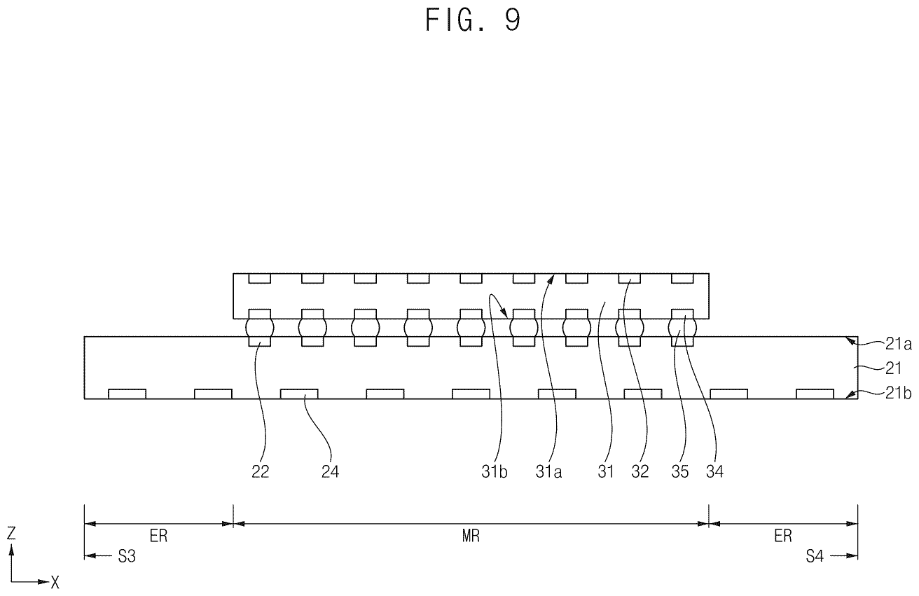

The interposer 30, the first semiconductor device 40, and the second semiconductor device 50 in FIG. 26 may be mounted on the package substrate 21 using substantially the same methods as the methods illustrated in FIGS. 9 to 11. Accordingly, a repeat description thereof will be omitted for conciseness.

Referring to FIGS. 27 to 29, an adhesive material TM may be applied to the edge region ER of the package substrate 21, a first stiffener 100 may be positioned on the adhesive material TM, and the first stiffener 100 may be attached to the package substrate 21 via the adhesive member 200 by heating the adhesive material TM while applying pressure to the first stiffener 100.

An adhesive material TM may be applied between the plurality of first substrate recesses SR1 and the plurality of second substrate recesses SR2 of the package substrate 21, respectively, and the first stiffener 100 may be positioned on the applied adhesive material. The first stiffener 100 may be positioned on the edge region ER of the package substrate 21 such that the plurality of first adhesive receiving grooves BR1 of the first stiffener 100 face the package substrate 21. For example, the adhesive material TM may be fluid since the adhesive material has low viscosity.

For example, the adhesive material TM may include a thermosetting epoxy material. The thermosetting epoxy material may be in a fluid state before heat is applied but may cure and solidify when exposed to heat. Further, the adhesive member 200 may include a filler to improve the adhesive performance of the adhesive member. The adhesive member 200 may include a thermal interface material (TIM). The thermal interface material may be a material that enhances thermal conductivity between two mating surfaces by facilitating heat transfer. Specifically, the thermal interface material may be a structure configured to effectively transfer heat between components by closely fitting the components so that there are no microscopic spaces between the components.

Then, the adhesive material TM may be heated to cure while moving the first stiffener 100 in the vertical direction toward the package substrate 21. The adhesive material may be flowable so that the adhesive material fills void between the first stiffener 100 and the package substrate 21, and then the adhesive material may be cured to integrally bond the first stiffener 100 and the package substrate 21.

The adhesive material may move in the horizontal direction as the first stiffener 100 moves down the package substrate 21. For example, the adhesive material may move from a center portion of the first stiffener 100 toward the plurality of first adhesive receiving grooves BR1 to fill the space between the first surface 100a of the stiffener 100 and the first surface 21a of the package substrate 21.

Thereafter, the adhesive material may at least partially fill the plurality of first substrate recesses SR1 and the plurality of second substrate recesses SR2, respectively. Then, a portion of the adhesive material may move in the vertical direction along the plurality of first adhesive recesses BR1 to fill a portion of each of the plurality of first adhesive recesses BR1. For example, each of the plurality of first adhesive receiving grooves BR1 may have a depth D. For example, in an example embodiment, the adhesive material may fill half of the depth D of the adhesive receiving groove.

For example, a portion of the adhesive material TM may move in the vertical direction to at least partially filling the plurality of first adhesive receiving grooves BR1 by capillary effect. The capillary effect may be a phenomenon in which a liquid inside a narrow tube moves itself inside the tube due to the surface tension of the liquid and the adhesion force of the liquid to the tube.

Thus, the adhesive material TM may fill the plurality of first substrate recesses SR1, the plurality of second substrate recesses SR2, and the plurality of first adhesive receiving grooves BR1 after covering all of the first surface 100a of the first stiffener 100. Thus, the plurality of first substrate recesses SR1, the plurality of second substrate recesses SR2, and the plurality of first adhesive receiving grooves BR1 can act as buffer spaces to prevent bleeding of the adhesive material from the package substrate 21 to the outside of the package substrate 21.

Further, the adhesive material may be cured by heat to form an adhesive member 200 configured to secure the first stiffener 100 and the package substrate 21.

Thus, the adhesive member 200 may cover all of the first surface 100a of the first stiffener 100 so that the adhesive member can provide sufficient adhesion between the first stiffener 100 and the package substrate 21.

While only a single package substrate 21 is illustrated in the figures, it will be appreciated that example embodiments are not limited thereto. Accordingly, the process illustrated in FIGS. 23 to 29 may be performed on a package array including a plurality of package substrates. However, in this case, a cutting process may be added to separate the package array into individual semiconductor packages.

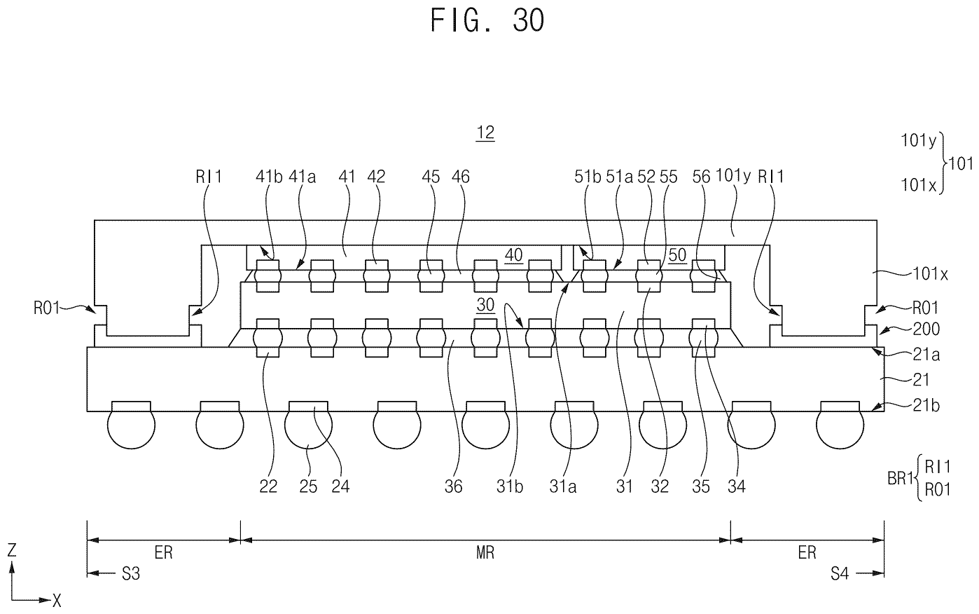

FIG. 30 is a cross-sectional view illustrating a semiconductor package in accordance with example embodiments.

The semiconductor package illustrated in FIG. 30 is substantially the same as the semiconductor package described in FIGS. 1 to 7E, with the exception of a second stiffener 101. Therefore, identical components are denoted by the same reference numerals and repeated descriptions of identical components are omitted for conciseness.

Referring to FIG. 30, the semiconductor package 12 may include a package substrate 21, an interposer 30 mounted on a mounting region MR of the package substrate 21, a first semiconductor device 40 and a second semiconductor device 50 mounted on the interposer 30, a second stiffener 101 provided on an edge region ER of the package substrate 21, and an adhesive member 200 provided between the package substrate 21 and the second stiffener 101.

In example embodiments, the second stiffener 101 may include a warpage prevention portion 101x provided on the edge region ER of the package substrate 21 and a heat dissipation portion 101y extending horizontally from an end portion of the warpage prevention portion 101x.

The warpage prevention portion 101x may extend in a vertical direction (e.g., a Z direction) from the package substrate 21. Additionally, the warpage prevention portion 101x may be integrally coupled to the package substrate 21 via the adhesive member 200. The warpage prevention portion 101x may include a plurality of first adhesive receiving grooves BR1 configured to control flow of the adhesive member 200. The warpage prevention portion may be a stiffener to prevent warping of the package substrate.

The warpage prevention portion 101x in FIG. 30 is substantially the same as the first stiffener 100 described in FIGS. 1 to 7e, and therefore, a repeat description thereof is omitted for conciseness.

The heat dissipation portion 101y may be provided on the first semiconductor device 40 and the second semiconductor device 50. For example, in some example embodiments, the heat dissipation portion 101y may be in direct contact with the first semiconductor device 40 and the second semiconductor device 50. In some example embodiments, the heat dissipation portion 101y may further include an interfacial adhesive member interposed between the first semiconductor device 40 and the second semiconductor device 50. For example, the interfacial adhesive member may include a thermal interface material (TIM).

The heat dissipation portion 101y may be a structure configured to dissipate heat generated by the first semiconductor device 40 and the second semiconductor device 50 to the outside. For example, the heat dissipation portion 101y may include a metallic material such as copper (Cu), aluminum (Al), or the like to improve the heat dissipation characteristics of the semiconductor package.

As described above, the second stiffener 101 of the semiconductor package 12 may include the heat dissipation portion 101y provided on the first semiconductor device 40 and the second semiconductor device 50.

Accordingly, the second stiffener 101 of the semiconductor package 12 can prevent warpage of the package substrate 21 and control the flow of the adhesive member 200 while improving the heat dissipation characteristics of the semiconductor package 12.

The package may include semiconductor devices such as logic devices or memory devices. The package may include, for example, logic devices such as a central processing unit (CPU, MPU), application processors (AP), volatile memory devices such as SRAM and DRAM devices, and non-volatile memory devices such as flash memory devices, PRAM, MRAM, and RRAM devices.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package comprising:
a package substrate including a mounting region and an edge region surrounding the mounting region;
at least one semiconductor device on the mounting region of the package substrate;
a stiffener on the edge region of the package substrate, the stiffener having a first surface facing the package substrate and a second surface opposite to the first surface; and
an adhesive member between the package substrate and the stiffener to attach the stiffener to the package substrate,
wherein the stiffener includes a reinforcement rod that reinforces the package substrate and a plurality of adhesive receiving grooves in a lower edge portion of the reinforcement rod that are exposed from side portions of the reinforcement rod, and
wherein each of the plurality of adhesive receiving grooves has a depth from the first surface of the stiffener to accommodate a portion of the adhesive member.

2. The semiconductor package of claim 1, wherein the stiffener includes an inner surface facing the at least one semiconductor device and an outer surface opposite to the inner surface, and
wherein the plurality of adhesive receiving grooves includes a plurality of inner recesses disposed along the inner surface of the stiffener to extend from the inner surface into the stiffener and a plurality of outer recesses disposed along the outer surface to extend from the outer surface of the stiffener into the stiffener.

3. The semiconductor package of claim 1, wherein an inner wall of each of the plurality of adhesive receiving grooves has a contact region and an exposed region, the contact region being in contact with the adhesive member and the exposed region being exposed to an outside of the semiconductor package.

4. The semiconductor package of claim 3, wherein the adhesive member includes:
a base portion in contact with the first surface of the stiffener; and
a vertical extension that extends from the base portion onto the contact region.

5. The semiconductor package of claim 4, wherein the vertical extension has a height that is less than the depth of each of the plurality of adhesive receiving grooves.

6. The semiconductor package of claim 4, wherein the first surface of the stiffener has a first width in a horizontal direction, and the base portion of the adhesive member has a second width in the horizontal direction that is greater than the first width.

7. The semiconductor package of claim 1, wherein the package substrate includes a plurality of substrate recesses on the edge region of the package substrate to at least partially accommodate the adhesive member.

8. The semiconductor package of claim 7, wherein the plurality of substrate recesses correspond respectively to the plurality of adhesive receiving grooves.

9. The semiconductor package of claim 1, wherein the stiffener includes:
a warpage prevention portion that extends in a vertical direction and includes the plurality of adhesive receiving grooves; and
a heat dissipation portion that extends in a horizontal direction from an end portion of the warpage prevention portion, the heat dissipation portion being in contact with the at least one semiconductor device.

10. The semiconductor package of claim 1, wherein the stiffener includes a metallic material, and the adhesive member includes a thermal interface material (TIM).

11. A semiconductor package comprising:
a package substrate including a mounting region and an edge region surrounding the mounting region;
an interposer disposed on the mounting region of the package substrate;
at least one semiconductor device mounted on the interposer;
a stiffener on the edge region of the package substrate, the stiffener including a reinforcement rod that reinforces the package substrate and a plurality of adhesive receiving grooves provided in a lower edge of the reinforcement rod and exposed from both side portions of the reinforcement rod; and
an adhesive member between the package substrate and the stiffener to attach the stiffener to the package substrate,
wherein the adhesive member covers a lower surface of the reinforcement rod and is at least partially accommodated in the plurality of adhesive receiving grooves.

12. The semiconductor package of claim 11, wherein the stiffener includes an inner surface facing the at least one semiconductor device and an outer surface opposite to the inner surface, and
wherein the plurality of adhesive receiving grooves includes a plurality of inner recesses disposed along the inner surface of the stiffener that extend from the inner surface into the stiffener, and a plurality of outer recesses disposed along the outer surface of the stiffener that extend from the outer surface into the stiffener.

13. The semiconductor package of claim 11, wherein an inner wall of each of the plurality of adhesive receiving grooves includes a contact region and an exposed region, the contact region being in contact with the adhesive member and the exposed region being exposed to the outside of the package substrate.

14. The semiconductor package of claim 13, wherein the adhesive member includes:
a base portion in contact with the lower surface of the reinforcement rod; and
a vertical extension extending from the base portion onto the contact region.

15. The semiconductor package of claim 11, wherein each of the plurality of adhesive receiving grooves has a circular shape, a triangular shape, a rectangular shape, or a polygonal shape, when viewed in a plan view.

16. The semiconductor package of claim 11, wherein the package substrate includes a plurality of substrate recesses on the edge region of the package substrate to at least partially accommodate the adhesive member.

17. The semiconductor package of claim 16, wherein the plurality of substrate recesses correspond respectively to the plurality of adhesive receiving grooves.

18. The semiconductor package of claim 11, wherein the stiffener includes,
a warpage prevention portion that extends in a vertical direction and includes the plurality of adhesive receiving grooves; and
a heat dissipation portion that extends in a horizontal direction from one end portion of the warpage prevention portion to be in contact with the at least one semiconductor device.

19. The semiconductor package of claim 11, wherein the stiffener includes a metallic material, and the adhesive member includes a thermal interface material (TIM).

20. A semiconductor package comprising:
a package substrate including a mounting region and an edge region surrounding the mounting region, the package substrate having first substrate recesses and second substrate recesses on the edge region and disposed along the mounting region;
at least one semiconductor device on the mounting region of the package substrate;
a stiffener on the edge region of the package substrate along an outer surface portion of the package substrate, the stiffener including a plurality of adhesive receiving grooves, the plurality of adhesive receiving grooves including a plurality of inner recesses and a plurality of outer recesses, the plurality of inner recesses extending from an inner surface of the stiffener into the stiffener and corresponding to the first substrate recesses, the plurality of outer recesses extending from an outer surface of the stiffener into the stiffener and corresponding to the second substrate recesses; and
an adhesive member between the package substrate and the stiffener to cover one surface of the stiffener, the adhesive member being at least partially accommodated in the plurality of adhesive receiving grooves.
